(19) United States
(12) Patent Application Publication
(10) Pub. No.: US 2008/0020493 A1
(43) Pub. Date: Jan. 24, 2008

(54) APPARATUS FOR SUPPLYING CHEMICAL, SEMICONDUCTOR MANUFACTURING APPARATUS HAVING THE SAME, AND METHOD FOR SUPPLYING CHEMICAL

(75) Inventors: Eun-Ok JIN, Gyeonggi-do (KR); Sang-Gon LEE, Gyeonggi-do (KR); Ho-Wang KIM, Seoul (KR); Tae-Young NAM, Seoul (KR); Chung-Guen HAN, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/754,246

(22) Filed: May 25, 2007

(30) Foreign Application Priority Data
May 25, 2006 (KR) 2006-47226

(51) Int. Cl. H01L 21/00; C23F 1/00

(52) U.S. Cl. 438/5; 438/14; 438/745; 156/345.15; 156/345.18

(57) ABSTRACT

Embodiments disclosed herein are generally directed to a chemical supplying apparatus, a semiconductor manufacturing equipment having the same and a method for supplying chemicals. The apparatus includes a tank, a first sensor, and a second sensor. The tank is filled with a liquid chemical and includes an outlet for the liquid chemical. The first sensor transmits a signal to a surface of the liquid chemical to detect a level of the liquid chemical within the tank. The probe includes a gap within which the liquid chemical can flow and the second sensor detects whether the liquid chemical are present inside the gap.

### CROSS-REFERENCE TO RELATED APPLICATIONS

This U.S. non-provisional patent application claims the benefit of foreign priority under 35 U.S.C. § 119 to Korean Patent Application No. 2006-47226, filed on May 25, 2006, the entire contents of which are hereby incorporated by reference.

### BACKGROUND

Embodiments of the present invention disclosed herein generally relate to an apparatus and a method for manufacturing semiconductor devices, and more particularly, to a chemical supplying apparatus for storing and supplying chemicals used for a semiconductor manufacturing process, a semiconductor manufacturing equipment having the same, and a method for supplying chemicals.

Buffer tanks are conventionally used in conjunction with semiconductor manufacturing equipment to store chemicals and ensure an even flow of chemicals to a process chamber. When an insufficient amount of chemical fills the buffer tank, process accidents can be easily generated. When an excessive amount of chemical fills the buffer tank, the chemicals may remain in a chemical supply pipe and act as a particle source. Therefore, it is almost always necessary to provide a sensor capable of measuring an amount of chemical that fills the buffer tank.

A conventional sensor for detecting a residual amount of chemical filling the buffer tank is a magnetic point sensor, as described in Korean Patent Publication No. 2005-114143 entitled “Chemical Supply Apparatus for a Semiconductor Equipment.” Korean Patent Publication No. 2005-114143 can be understood to disclose wherein a magnetic point sensor is a ball-shaped and is risibly combined by buoyancy to a sensing bar installed inside a chemical storing tank. This magnetic point sensor rises and falls according to a surface level of a liquefied chemical within the chemical storing tank to monitor the amount of liquefied chemical within the chemical storing tank.

Another conventional sensor is described in Korean Patent Publication No. 2002-67148 entitled “Chemical Supplying Apparatus for Semiconductor Manufacturing.” Korean Patent Publication No. 2002-67148 can be understood to disclose a load cell coupled to a buoyant pendulum by a connecting strip. While the buoyant pendulum moves depending on a surface level of liquefied chemical, the weight of the buoyant pendulum acting on the load cell changes.

The former conventional sensor advantageously allows the storage level of various liquefied chemicals to be detected, indicates when the storage level of the liquefied chemicals is low and when new chemicals need to be supplemented, and indicates when the storage level of the liquefied chemicals is high and the supplementing of new chemicals needs to be suspended. The latter conventional sensor advantageously indicates a storage level of various chemicals.

According to the former conventional sensor, magnetic ball-type point sensor contacts the liquefied chemical and may, therefore, become a potential particle generation source. According to the latter conventional sensor load cell type sensor, there is a possibility that accuracy in measurement may be reduced because waves are generated when the liquefied chemical flows in and out of the storage tank. Therefore, an improved chemical supplying apparatus capable of always monitoring a point at which chemicals need to be supplemented and even indicating a point at which supplying the chemicals needs to be suspended, as well as a residual amount of chemicals, while suppressing particle generation and not influencing product quality is required.

### SUMMARY

The present invention provides a chemical supplying apparatus capable of always monitoring a storage level of chemicals while not generating particles, a semiconductor manufacturing equipment having the same, and a chemical supplying method.

One embodiment exemplarily described herein can be generally characterized as a liquid supplying apparatus that includes a tank adapted to store a liquid within an interior thereof, an outlet in fluid communication with the interior of the tank; a first sensor adapted to detect a surface level of the liquid within the interior of the tank; a probe within the interior of the tank; and a second sensor coupled to a portion of the probe. The second sensor may be adapted to detect the presence of liquid adjacent to the portion of the probe.

Another embodiment exemplarily described herein can be generally characterized as a chemical supplying apparatus that includes a tank adapted to store a liquid within an interior thereof; an inlet in fluid communication with the interior of the tank; an outlet in fluid communication with the interior of the tank; a separation plate spaced apart from a bottom surface and at least partially defining the interior of the tank and including a recessed portion coinciding with an axis of the outlet; a continuous sensor located between the bottom surface of the tank and the recessed portion of the separation plate; and a plurality of process-control sensors located within the interior of the tank. The inlet may be adapted to supply liquid into the interior of the tank. The outlet may be adapted to remove liquid from the interior of the tank. The continuous sensor may be adapted to detect a surface level of liquid stored within the interior of the tank over a range of continuous levels within the interior of the tank. The plurality of process-control sensors may be adapted to detect the presence of liquid at particular levels within the interior of the tank and generate signals indicating whether the interior of the tank contains less than a first threshold amount of liquid, whether the interior of the tank contains more than a second threshold amount of liquid greater than the first threshold amount, whether a supplemental amount of liquid should be supplied to the interior of the tank and whether supplying of the supplemental amount of liquid should be suspended based upon the detected presence or absence of liquid at the particular levels.

Yet another embodiment exemplarily described herein can be generally characterized as a semiconductor manufacturing equipment that includes a process chamber adapted to perform a semiconductor manufacturing process; a main tank adapted to store a chemical used in the process chamber; a buffer tank coupled between the process chamber and the main tank; and a controller coupled to the main tank, the buffer tank, and the process chamber. The main tank may be adapted to supply the chemical to an interior of the buffer tank and the buffer tank is adapted to store the chemical in a liquefied form. The buffer tank may include a continuous sensor unit and a process-control sensor unit. The continuous sensor unit may be adapted to monitor an amount of the chemical stored within the interior of the buffer tank and generate a signal based upon the monitored amount of the chemical. The process-control sensor unit may be adapted to detect the presence of the chemical at particular levels within the interior of the buffer tank and generate a signal based upon the detected presence or absence of the chemical. The controller may be adapted to receive the signal generated by the process-control sensor unit, may be adapted to control the semiconductor manufacturing process of the process chamber and may further be adapted to control the main tank to supply the chemical to the interior of the buffer tank.

Still another embodiment exemplarily described herein can be generally characterized as a method of manufacturing a semiconductor device that includes detecting the presence of a chemical contained within the interior of a first tank at particular levels within the interior of the first tank, wherein the first tank is coupled to a process chamber that is adapted to perform a semiconductor manufacturing process using the chemical; generating a signal based on the detecting; and determining whether to permit the semiconductor manufacturing process to be performed and whether to permit a supplemental amount of the chemical to be supplied from a second tank to the first tank based upon the generated signal.

### BRIEF DESCRIPTION OF THE FIGURES

The accompanying figures are included to provide a further understanding of the embodiments described herein, and are incorporated in and constitute a part of this specification. The drawings exemplarily illustrate the embodiments described herein and, together with the description, serve to explain principles of the present invention. In the figures:

FIG. 1 is a view illustrating a semiconductor manufacturing equipment having a chemical supplying apparatus according to one embodiment;

FIG. 2 is a cross-sectional view of a chemical supplying apparatus according to one embodiment;

FIG. 3 is an enlarged cross-sectional view of region A of the chemical supplying apparatus shown in FIG. 2, according to one embodiment;

FIG. 4 is an enlarged cross-sectional view of region B of the chemical supplying apparatus shown in FIG. 2, according to one embodiment;

FIGS. 5 and 6 are cross-sectional views exemplarily illustrating one embodiment of detecting liquid chemicals at a point sensor of the chemical supplying apparatus shown in FIG. 2;

FIGS. 7 and 8 are enlarged cross-sectional views of region B of the chemical supplying apparatus shown in FIG. 2, according to another embodiment, which exemplarily illustrate another embodiment of detecting liquid chemicals in the chemical supplying apparatus shown in FIG. 2; and

FIGS. 9 and 10 are views exemplarily illustrating one embodiment of an operation of semiconductor manufacturing equipment incorporating the chemical supplying apparatus shown in FIG. 2.

### DETAILED DESCRIPTION

Exemplary embodiments of the present invention will be described below in more detail with reference to the accompanying drawings. These embodiments may, however, be realized in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout. Hereinafter, it will be described about an exemplary embodiment of the present invention in conjunction with the accompanying drawings.

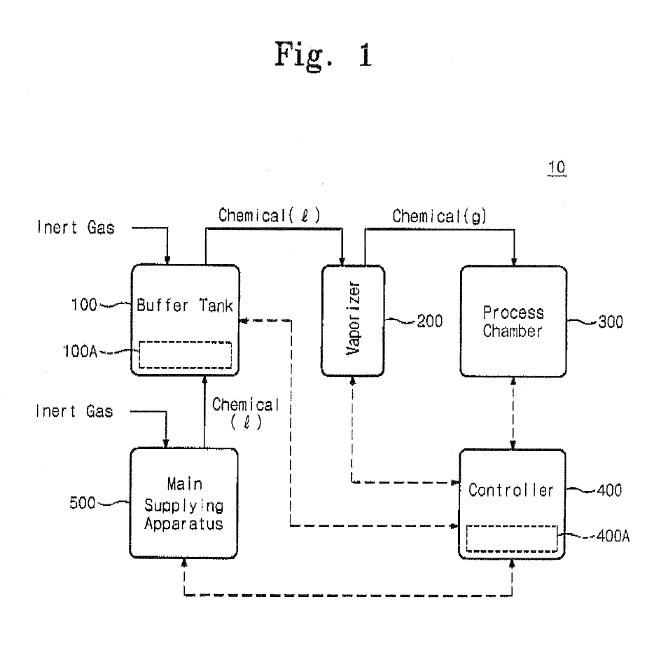

FIG. 1 is a view illustrating a semiconductor manufacturing equipment having a chemical supplying apparatus according to one embodiment.

Referring to FIG. 1, a semiconductor manufacturing equipment 10 (hereinafter referred to as “equipment 10”) vaporizes a liquid chemical (precursor) and uses the vaporized chemical (Chemical (g)) to perform a semiconductor manufacturing process within a process chamber 300. The liquid chemical is stored in a main supplying apparatus 500 in a liquid state and undergoes a phase-transition to a vapor state in a vaporizer 200. A buffer tank 100, used as a temporary storage and supply apparatus of liquid chemical, is provided to the equipment 10 to ensure a stable supply of liquid chemical (Chemical (l)). Also, a controller 400 containing circuitry for controlling operations of the buffer tank 100, vaporizer 200, process chamber 300 and main supplying apparatus 500 is provided. As used herein, the term “circuitry” refers to any type of executable instructions that can be implemented, for example, as computer hardware, firmware, and/or software, which are all within the scope of the various teachings described. The controller 400 may include a display unit 400A for visually displaying, for example, a residual amount of liquid chemical within the buffer tank 100 and a process progress status. In one embodiment, a display unit 10A can be provided to the buffer tank 100 to facilitate checking the residual amount of liquid chemical within the buffer tank 100.

The liquid chemical may be provided to the buffer tank 100 from the main supplying apparatus 500, and be temporarily stored within the buffer tank 100. The liquid chemical temporarily stored in the buffer tank 100 may be provided to the vaporizer 200. The vaporizer 200 causes the liquid chemical to undergo a phase-transition to a vaporized state. The vaporized chemical may then flow from the vaporizer 200 into the process chamber 300 and be used for semiconductor manufacturing processes such as chemical vapor deposition (CVD). When the main supplying apparatus 500 is pressurized by the introduction of an inert gas, liquid chemical stored in the main supplying apparatus 500 can be provided to the buffer tank 100. Providing the liquid chemical from the buffer tank 100 to the vaporizer 200 may also be performed by pressurizing the buffer tank 100 using an inert gas.

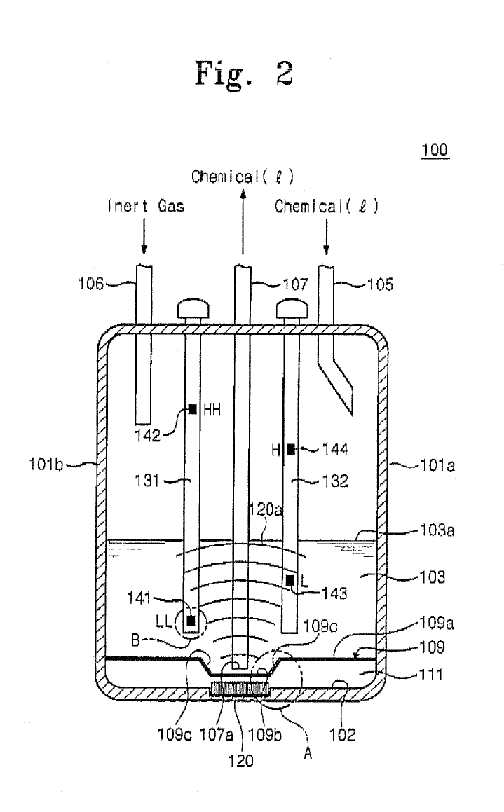

FIG. 2 is a cross-sectional view of a chemical supplying apparatus according to one embodiment.

Referring to FIG. 2, an outlet pipe 107 and an inlet pipe 105 through which liquid chemicals flow out and in, respectively, may be disposed in the buffer tank 100 (i.e., in fluid communication with an interior of the buffer tank 100). The outlet pipe 107 may be installed in a central portion of the buffer tank 100 and the inlet pipe 105 may be installed to be close to a first wall 101a (e.g., a right wall) of the buffer tank 100. A gas pipe 106, through which an inert gas (e.g., argon, neon, and the like) used for pressurizing the interior of the buffer tank 100 flows, may be installed to be close to a second wall 101b (e.g., a left wall) of the buffer tank 100. The liquid chemical 103 may flow through the outlet pipe 107 when the interior of the buffer tank 100 is pressurized.

According to some embodiments, the storage level of liquid chemical 103 within the buffer tank 100 is detectable. A supplemental amount of liquid chemical 103 can be supplied or not suspended as needed. When an amount of liquid chemical 103 within the buffer tank 100 is too low or too high, an interlock signal may be generated to prevent the semiconductor manufacturing equipment 10 from functioning improperly. Accordingly, the buffer tank 100 may include a continuous sensor 120 for detecting a level of a liquid surface 103a of the liquid chemical 103 over a range of continuous levels within the buffer tank 100 to monitor an amount of liquid chemical 103 within the buffer tank 100. Accordingly, the continuous sensor 120 allows an amount of liquid chemical 103 within the buffer tank 100 to be monitored over a range of continuous levels. In one embodiment, the continuous sensor 120 may be provided as an ultrasonic transceiver (or an ultrasonic transmitter and receiver) that incorporates, for example, a piezoelectric element.

If the continuous sensor 120 contacts the liquid chemical 103, there is a possibility that particles can be generated within the liquid chemical 103. Moreover, if a fine gap is generated in the continuous sensor 120, there is a possibility that the liquid chemical 103 may flow into the gap and cause the continuous sensor 120 to function improperly. Therefore, in one embodiment, the continuous sensor 120 may be provided so as to not contact the liquid chemical 130. For example, the continuous sensor 120 may be installed in a vacant space 111 between a bottom surface 102 and a separation plate 109 of the buffer tank 100. The separation plate 109 may separate the continuous sensor 120 from the liquid chemical 103, so that the continuous sensor 120 does not contact the liquid chemical 103.

In the illustrated embodiment, a central region of the surface of the separation plate 109 may be recessed. For example, the separation plate 109 may include a relatively high surface 109a and a relatively low surface 109b. In one embodiment, the separation plate 109 may include an inclined surface 109c between the relatively high surface 109a and the relatively low surface 109b. In one embodiment, the relatively high surface 109a may be substantially flat. In another embodiment, the relatively high surface 109a may be sloped toward a central axis of the buffer tank 100. The outlet pipe 107 has an entry portion 107a through which the liquid chemicals 103 may flow into. The entry portion 107a may be disposed closer to the relatively low surface 109b than the relatively high surface 109a. With this construction, the portion of the liquid chemical 103 stored in the buffer tank 100 that is located over the relatively low surface 109b of the separation plate 109 flows out through the outlet pipe 107 before, for example, the portion of the liquid chemical 103 stored in the buffer tank 100 that is located over the relatively high surface 109a. The possibility of characteristic reduction and change generation caused by accumulation of the chemicals 103 can be excluded by supplying first the portion of the liquid chemicals 103 that is located in a lowermost part of the buffer tank 100.

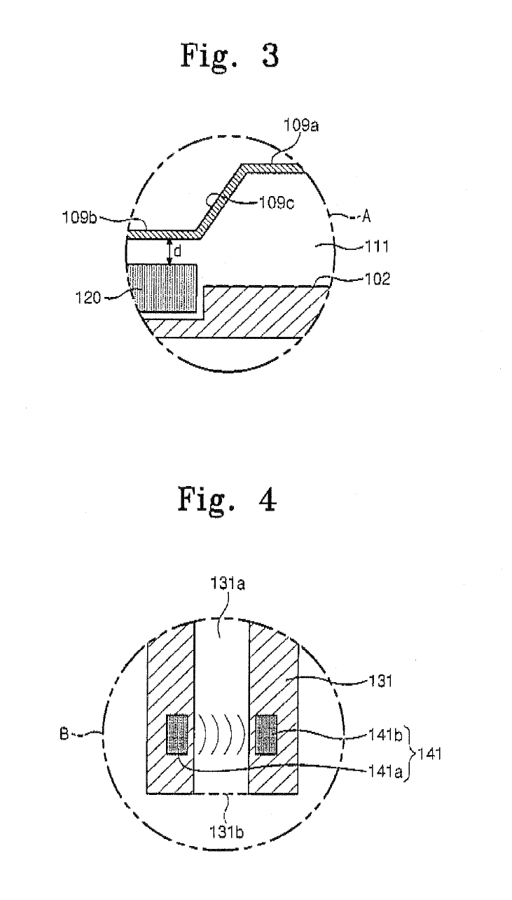

FIG. 3 is an enlarged cross-sectional view of region A of the chemical supplying apparatus shown in FIG. 2, according to one embodiment.

Referring to FIG. 3, the continuous sensor 120 may have a dead zone in a region immediately thereabove where adequate measurements cannot be easily made. In such embodiments, the continuous sensor 120 may be spaced apart from the relatively low surface 109b of the separation plate 109 by predetermined distance ‘d’ to ensure that the liquid surface 103a to be measured will not be located within the dead zone. In one embodiment, the dead zone of the continuous sensor 120 is included within the space between the continuous sensor 120 and the relatively low surface 109b of the separation plate 109.

Referring back to FIG. 2, the continuous sensor 120 generates ultrasonic waves (i.e., signals) 120a which are transmitted through the liquid chemical 103 to the liquid surface 103a thereof, and detects ultrasonic waves reflected by the liquid surface 103 a and transmitted through the liquid chemical 103 to detect a level of the liquid surface 103a within the buffer tank 100. By this method, the continuous sensor 120 can monitor an amount of the liquid chemical 103 within the buffer tank 100.

Bubbles may be generated within the liquid chemical 103 due to the ultrasonic waves. These bubbles might diffuse the reflected ultrasonic waves and, as a result, make it difficult to accurately measure the level of the liquid surface 103a with the continuous sensor 120 alone. Accordingly, in one embodiment, a plurality of process-control sensors 141, 142, 143, and 144 (e.g., ultrasonic sensors) may be distributed on a plurality of probes.

In one embodiment, a first probe 131 and a second probe 132 may be located on opposite sides of the outlet pipe 107 and extend along a direction (e.g., a vertical direction) in which the level of the liquid surface 103a changes. In another embodiment, the probes may remain substantially stationary along the direction in which the level of the liquid surface 103a changes within the interior of the buffer tank 100. The plurality of process-control sensors 141, 142, 143, and 144 may be provided as point sensors arranged at particular positions on the first and second probes 131 and 132 to detect the presence or absence of the liquid chemical 103 at particular levels within the buffer tank 100.

In the illustrated embodiment, a first process-control sensor 141 may be located at a lowermost portion to detect an empty alarm level of the liquid chemical 103 and generate an empty alarm signal (i.e., a low-low (‘LL’) signal). A second process-control sensor 142 may be located at an uppermost location to detect an overflow alarm level of the liquid chemical 103 and generate an overflow alarm signal (i.e., a high-high (‘HH’) signal). A third process-control sensor 143 may be located between the first and second process-control sensors 141 and 142 to detect a supplement level of the liquid chemical 103 and generate a low (‘L’) signal. A fourth process-control sensor 144 may be located between the second and third process-control sensors 142 and 143 to detect a supplement suspension level of the liquid chemical 103 and generate a high (‘H’) signal.

In one embodiment, the first and second process-control sensors 141 and 142 may, for example, be arranged on the first probe 131 and the third and fourth process-control sensors 143 and 144 may, for example, be arranged on the second probe 132. In the event that the first to fourth process-control sensors 141-144 are not operating, an amount of liquid chemical 103 can still be measured using the continuous sensor 120.

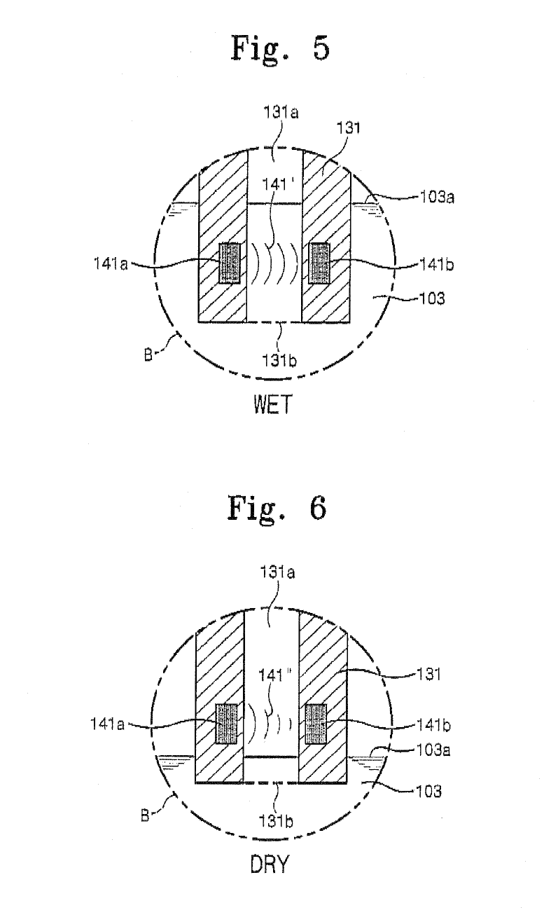

FIG. 4 is an enlarged cross-sectional view of region B of the chemical supplying apparatus shown in FIG. 2, according to one embodiment.

Referring to FIG. 4, a gap 131 a may be defined inside the first probe 131. In one embodiment, the gap 131 a may extend through opposite lateral sides of the first probe 131. The first process-control sensor 141 may include an emitter 141a and receiver 141b disposed within the first probe 131 to face each other with the gap 131a interposed therebetween. The emitter 141a may, for example, be installed within the first probe 131 at a left side of the gap 131a and the receiver 141b may, for example, be installed within the first probe 131 at a right side of the gap 131a such that the emitter 141a and receiver 141b do not contact the liquid chemical 103. In one embodiment, the emitter 141a emits an ultrasonic wave (i.e., a signal) and the receiver 141b detects the ultrasonic wave emitted by the emitter 141a. Based upon the intensity of the detected ultrasonic wave, the process-control sensor 141 can detect whether liquid chemical 103 is present or absent within the gap 131a. In one embodiment, the gap 131a extends along a direction (e.g., a vertical direction) in which a level of the liquid surface 103a changes. In one embodiment, the gap 131a may have a length sufficient to allow the liquid surface 103a of the liquid chemical 103 within the gap 131a rise above and below the first process-control sensor 141. In another embodiment, an the gap 131a may be open to the lowermost portion of the probe 131 at open portion 131b to allow the liquid chemical 103 to flow into and out of the gap 131a. Descriptions of other process-control sensors 142-144 and the probe 132 may be the same as those described above.

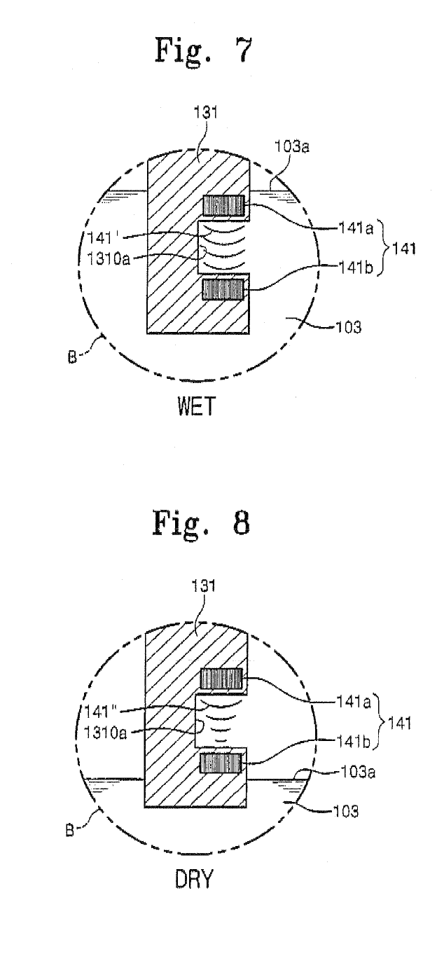

FIGS. 5 and 6 are cross-sectional views exemplarily illustrating one embodiment of detecting liquid chemical at a process-control sensor of the chemical supplying apparatus shown in FIG. 2.

As illustrated, the liquid chemical 103 may flow into the gap 131a (e.g., via the open portion 131b). When the liquid surface 103a is positioned higher than the emitter 141a and the receiver 141b (as shown in FIG. 5), an ultrasonic wave (i.e., a signal) generated by the emitter 141a is transmitted through the liquid chemical 103 and is detected by the receiver 141b as an ultrasonic wave 141′ having an intensity above a certain threshold. Accordingly, the first process-control sensor 141 generates a ‘WET” signal to indicate that the liquid chemical 103 are present within the gap 131a. However, when the liquid chemical 103 does not fill the gap 131a or when the liquid surface 103a is positioned lower than the emitter 141a and the receiver 141b (as shown in FIG. 6), an ultrasonic wave emitted by the emitter 141a passes through air and is detected by the receiver 141b as an ultrasonic wave 141″ having an intensity below the certain threshold. The intensity of the ultrasonic wave 141″ is understood to be below the certain threshold because the ultrasonic wave emitted by the emitter 141a becomes considerably attenuated as it is transmitted through the air. In some embodiments, the ultrasonic wave 141″ may not be detected by the receiver 141b. Accordingly, the first process-control sensor 141 generates a ‘DRY’ signal to indicate that the liquid chemical 103 are absent from the gap 131a. Thus, the ‘DRY’ signal generated by the first process-control sensor 141 may correspond to the aforementioned empty alarm signal or ‘LL’ signal. As described above, the first process-control sensor 141 detects whether the liquid chemical 103 are present within the gap 131a using a principle that intensity of the ultrasonic wave emitted by the emitter 141a is considerably reduced when it does not pass through the liquid chemical 103. In some embodiments, the other process-control sensors 142-144 may operate based on the same principle as that of the first process-control sensor 141. In the case of the second process-control sensor 142, however, a ‘WET’ signal may correspond to the aforementioned overflow alarm signal or ‘HH’ signal.

In one embodiment, the ability of the process-control sensors 141-144 to detect the presence of liquid chemical 103 may be different between each sensor to minimize the possibility that an insufficiently or excessively filled buffer tank 100 may cause semiconductor processes within the process chamber 300 to be improperly performed. For example, the first process-control sensor 141 may be provided to be more sensitive than other process-control sensors in detecting the absence of the liquid chemical 103. On the other hand, the second process-control sensor 142 may be provided to be more sensitive than other process-control sensors in detecting the presence of the liquid chemical 103. This can be realized by appropriately controlling the ability of the first and second process-control sensors 141 and 142 to generate the ‘WET’ and ‘DRY’ signals (i.e., by controlling a dry-wet detection ratio of the first and second process-control sensors 141 and 142).

In one embodiment the dry-wet detection ratio can be controlled by comparing the number of times the emitter 141 a emits ultrasonic waves with the number of times the receiver 141b receives ultrasonic waves 141′ and 141″. In one embodiment, the comparing may be performed at the receiver 141b. Based on the comparing, the first process-control sensor 141 may generate a ‘DRY’ signal instead of a ‘WET’ signal even if the receiver 141b received more ultrasonic waves 141′ than ultrasonic waves 141″. Thus, if the emitter 141a emits ultrasonic waves a total of, for example, ten times and the receiver 141b receives ultrasonic waves 141′ a total of seven times and ultrasonic waves 141″ a total of three times, then the first process-control sensor 141 may nevertheless generate a ‘DRY’ signal. In this sense, the first process-control sensor 141 may more sensitively detect the absence of the liquid chemical 103 than the second process-control sensor 142.

On the other hand, the number of times the emitter of the second process-control sensor 142 emits ultrasonic waves can be compared with the number of times the receiver of the second process-control sensor 142 receives ultrasonic waves like 141′ and 141″. In one embodiment, the comparing may be performed at the receiver of the second process-control sensor 142. Based on the comparing, the second process-control sensor 142 may generate a ‘WET’ signal instead of a ‘DRY’ signal even if the receiver received more ultrasonic waves 141″ than ultrasonic waves 141′. Thus, if the emitter emits ultrasonic waves a total of, for example, ten times and the receiver receives ultrasonic waves 141″ a total of seven times and ultrasonic waves 141′ a total of three times, then the second process-control sensor 141 may nevertheless generate a ‘WET’ signal. In this sense, the second process-control sensor 142 may more sensitively detect the presence of the liquid chemical 103 than the first process-control sensor 141.

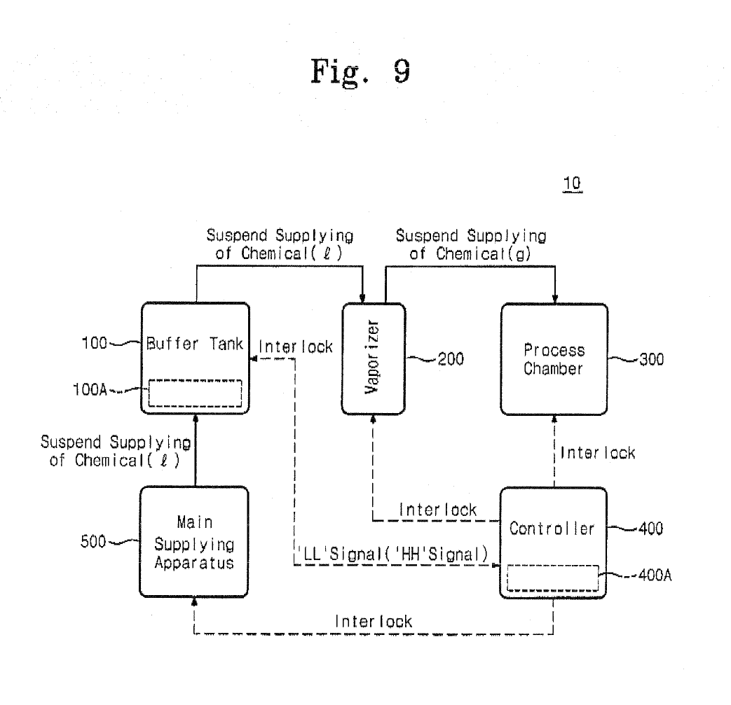

FIGS. 7 and 8 are enlarged cross-sectional views of region B of the chemical supplying apparatus shown in FIG. 2, according to another embodiment, which exemplarily illustrate another embodiment of detecting liquid chemical in the chemical supplying apparatus shown in FIG. 2.

Referring to FIG. 7, a gap may be defined within the first probe 131 and be recessed from lateral side of the probe 131 to define a recessed surface 1310a therein. The first process-control sensor 141 may include an emitter 141a (e.g., an ultrasonic emitter) and receiver 141b disposed within the first probe 131 to face each other with the recessed surface 1310a interposed therebetween. When liquid chemical 103 is present inside the gap (e.g., so as to contact the recessed surface 1310a), an ultrasonic wave emitted by the emitter 141a is received at the receiver 141b via the liquid chemical 103 as an ultrasonic wave 141′ and the first process-control sensor 141 may generate a ‘WET’ signal. On the other hand, when the liquid chemical 103 is absent from inside the gap (e.g., so as to not contact the recessed surface 1310a) as exemplarily illustrated in FIG. 8, the intensity of the ultrasonic wave generated by the emitter 141a is considerably reduced and the receiver 141b either receives a reduced-intensity ultrasonic wave 141″ or no ultrasonic wave at all. As a result, the first process-control sensor 141 may generate a ‘DRY’ signal. Descriptions of other process-control sensors 142-144 and the probe 132 may be the same as those described above.

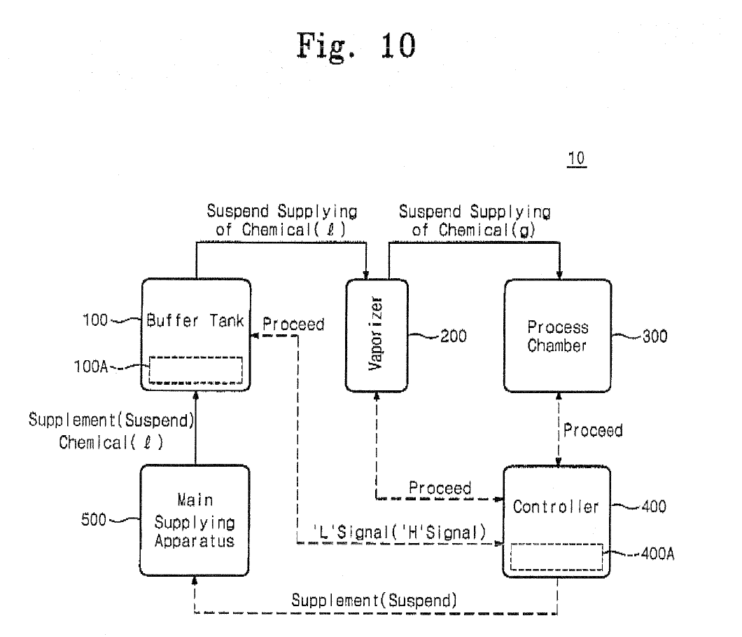

FIGS. 9 and 10 are views exemplarily illustrating one embodiment of an operation of semiconductor manufacturing equipment incorporating the chemical supplying apparatus shown in FIG. 2.

Referring to FIG. 9, when an empty alarm signal (an ‘LL’ signal) of liquid chemical 103 is transmitted to the controller 400 as a result of detecting a residual amount of the liquid chemical 103 stored in the buffer tank 100, the controller 400 generates an interlock signal (Interlock). The interlock signal may be transmitted to the buffer tank 100, the vaporizer 200, the process chamber 300 and the main supplying apparatus 500. Upon transmitting the interlock signal, the supply of liquid chemical from the buffer tank 100 to the vaporizer 200 may be suspended, the supply of vapor chemicals from the vaporizer 200 to the process chamber 300 may be suspended, the supply of liquid chemical from the main supplying apparatus 500 to the buffer tank 100 may also be suspended and processes being performed within the process chamber 300 may be suspended. The controller 400 may also generate the aforementioned interlock signal when an overflow alarm signal (an ‘HH’ signal) of the liquid chemical 103 is transmitted to the controller 400 from the buffer tank 100.

Referring to FIG. 10, when a supplement supply signal (an ‘L’ signal) indicating that the liquid chemical 103 needs to be supplemented is transmitted to the controller 400 as a result of detecting an amount of the liquid chemical 103 stored in the buffer tank 100 and the controller 400 generates a proceed signal (Proceed) and a supplement signal (Supplement). The proceed signal may be transmitted to the buffer tank 100, the vaporizer 200 and the process chamber 300. The supplement signal may be transmitted to the main supplying apparatus 500. Upon transmitting the proceed signal, the buffer tank 100, vaporizer 200, and process chamber 300 operate normally. Upon transmitting the supplement signal, the main supplying apparatus 500 is controlled to supply a supplemental amount of liquid chemical 103 to the buffer tank 100. Accordingly, the vaporizer 200 receives liquid chemical 103 from the buffer tank 100 to vaporize the received liquid chemical and the process chamber 300 receives vaporized chemicals from the vaporizer 200 to perform a process therein without interruption while the amount of liquid chemical 103 in the buffer tank 100 is increased. It will be appreciated that the ‘L’ signal may be generated when the third process-control sensor 143 generates a ‘DRY’ signal as described above with respect to, for example, FIG. 6.

While the supplemental amount of liquid chemical is provided to the buffer tank 100, a supplement supply suspension signal (an ‘H’ signal) of the liquid chemical 103 may be transmitted to the controller 400 to indicate when the liquid chemical no longer needs to be supplemented to the buffer tank 100. Upon receipt of the H signal, the controller 400 generates the aforementioned proceed signal so that the buffer tank 100, vaporizer 200, and process chamber 300 operate normally and also generates a suspend signal (Suspend) to control the main supplying apparatus 500 to suspend supplementing liquid chemical 103 to the buffer tank 100. It will be appreciated that the ‘H’ signal may be generated when the fourth process-control sensor 144 generates a ‘WET’ signal as described above with respect to, for example, FIG. 5.

As described above, an amount of liquid chemical within a buffer tank can be monitored using a continuous sensor to detect a level of the liquid chemical within the buffer tank over a range of continuous levels. Also, empty and overflow alarm levels, as well as supplement and supplement suspension levels of the liquid chemical can be detected using process-control sensors. Therefore, according to the present invention, it is possible to secure a stable supply of liquid chemical and thus remarkably reduce the likelihood processes from being improperly performed by appropriately controlling the amount liquid chemical within the buffer tank.

As described above, some embodiments exemplarily described above provide chemical supplying apparatuses for monitoring an amount of liquid chemical using an ultrasonic sensor for detecting a continuous liquid water level of the liquid chemical and another ultrasonic sensor for detecting a particular liquid water level of the liquid chemical.

In some embodiments, a chemical supplying apparatus includes a tank filled with liquid chemical and including an outlet for the liquid chemical; a first sensor for illuminating a predetermined signal to a liquid surface of the liquid chemical to detect a level of the liquid chemical; a probe having a gap in which the liquid chemical flows; and a second sensor for detecting whether the liquid chemical exit inside the gap to detect a level of the liquid chemical.

In some embodiments, the first sensor is an ultrasonic sensor located on a bottom surface of the tank to illuminate a predetermined signal to a liquid surface of the liquid chemical, and to detect a signal reflected by the liquid surface to detect a level of the liquid chemical.

In other embodiments, the tank includes a separation plate having a first surface separated from a bottom surface of the tank, and the first sensor is installed in a vacant space formed between the separation plate and the bottom surface. The separation plate includes a second surface located at a position corresponding to an upper end of the ultrasonic sensor and having a lower height than that of the first surface, and the second surface is close further to an entry of the outlet than the first surface.

In still other embodiments, the second sensor comprises a plurality of ultrasonic sensors including an emitter and a receiver installed inside the probe to face each other with the gap interposed. The probe has a length extending in a direction in which a level of the liquid chemical changes, and the gap extends in a length direction of the probe. The gap comprises an entry opened toward a bottom surface of the tank.

In even other embodiments, the probe has a length extending in a direction in which a level of the liquid chemical changes, and the gap has a shape recessed from a lateral side of the probe.

In yet other embodiments, the plurality of ultrasonic sensors include a first ultrasonic sensor for detecting an empty level of the liquid chemical; a second ultrasonic sensor for detecting a supplement level of the liquid chemical; a third ultrasonic sensor for detecting a supplement suspension level of the liquid chemical; and a fourth ultrasonic sensor for detecting an overflow level of the liquid chemical. The probe includes a first probe in which the first ultrasonic sensor and the fourth ultrasonic sensor are installed; and a second probe in which the second ultrasonic sensor and the third ultrasonic sensor are installed.

In further embodiments, each of the first through fourth ultrasonic sensors compares the number of first signals generated when the liquid chemical is absent inside the gap with the number of second signals generated when the liquid chemical is present inside the gap to detect a level of the liquid chemical. The first ultrasonic sensor detects that the liquid chemical is absent even though the number of the first signals is smaller than that of the second signals. The fourth ultrasonic sensor detects that the liquid chemical is present even though the number of the first signals is greater than that of the second signals.

In still further embodiments, the first sensor detects a continuous level of the liquid chemical, and the second sensor detects a particular level of the liquid chemical.

In still other embodiments of the present invention, a chemical supplying apparatus includes a tank for storing liquid chemical and having an outlet for the liquid chemical; a separation plate installed apart a predetermined distance from a bottom surface of the tank at a lower portion of the tank and having a recessed portion close to an entry of the outlet; a continuous sensor installed between the bottom surface and the separation plate below the recessed portion not to contact the liquid chemical, for illuminating ultrasonic waves to a liquid surface of the liquid chemical and detecting ultrasonic waves reflected by the liquid surface to detect a continuous level of the liquid chemical, thereby monitoring a residual amount of the liquid chemical; a probe installed inside the tank to extend in a direction in which a level of the liquid chemical changes, and having a gap in which the liquid chemical flows; and point sensors including a plurality of ultrasonic sensors for informing whether the liquid chemical is empty, overflowing, or supplemented, the plurality of ultrasonic sensors being installed in a direction in which a level of the liquid chemical changes to detect a particular level of the liquid chemical by detecting whether the liquid chemical is present inside the gap without contacting with the liquid chemical.

In some embodiments, the continuous sensor is separated from the separation plate, and a vacant space is formed between the continuous sensor and the separation plate.

In other embodiments, the gap extends in a direction in which a level of the liquid chemical changes to allow the plurality of ultrasonic sensors to detect a level of the liquid chemical that has flowed into the gap.

In still other embodiments, each of the plurality of ultrasonic sensors includes an emitter for generating ultrasonic waves and a receiver for detecting the ultrasonic waves generated by the emitter, and the emitter and the receiver face each other with the gap interposed.

In even other embodiments, the probe includes: a first probe in which a first ultrasonic sensor of the plurality of ultrasonic sensors, for detecting an empty level of the liquid chemical and a second ultrasonic sensor of the plurality of ultrasonic sensor, for detecting an overflow level of the liquid chemical are installed; and a second probe in which a third ultrasonic sensor of the plurality of ultrasonic sensor, for detecting a supplement level of the liquid chemical and a fourth ultrasonic sensor of the plurality of ultrasonic sensors, for detecting a supplement suspension level of the liquid chemical are installed.

In yet other embodiments, the first ultrasonic sensor more sensitively detects absence of the liquid chemical than the second ultrasonic sensor, and the second ultrasonic sensor more sensitively detects presence of the liquid chemical than the first ultrasonic sensor.

In even other embodiments of the present invention, semiconductor manufacturing equipments include: a process chamber for performing a predetermined process; a main tank for storing chemical used in the process chamber; a buffer tank including a continuous sensor unit for detecting a storage level of the chemical provided from the main tank to monitor a residual amount of the chemical, and a point sensor unit for detecting the presence of the chemical at a particular level of the storage level to inform a residual level of the chemical; and a controller for receiving signals regarding a level of the chemical from the continuous sensor unit and the point sensor unit to control whether to proceed the process and supplement chemical from the main tank to the buffer tank.

In some embodiments, the continuous sensor unit includes an ultrasonic sensor located on a bottom surface of the buffer tank such that it does not contact the chemical to illuminate an ultrasonic wave to a liquid surface of the chemical, and to detect an ultrasonic wave reflected by the liquid surface to detect a continuous level of the liquid chemical.

In other embodiments, the point sensor unit includes: a probe extending in a direction in which a level of the chemical changes and having a gap in which the chemical flows; and a plurality of ultrasonic sensors arranged in a length direction of the probe, for receiving an ultrasonic signal delivered by the medium of the chemical and detecting presence of the chemical when the gap is filled with the chemical, to detect a particular level of the chemical.

In still other embodiments, the plurality of ultrasonic sensors include: a first ultrasonic sensor installed at a lowermost position of the probe to detect an empty level of the chemical; a second ultrasonic sensor installed at an uppermost position of the probe to detect an overflow level of the chemical; a third ultrasonic sensor installed between the first ultrasonic sensor and the second ultrasonic sensor to detect a supplement level of the chemical; and a fourth ultrasonic sensor installed between the second ultrasonic sensor and the third ultrasonic sensor to detect a supplement suspension level of the chemical.

In even other embodiments, the controller suspends providing the chemical from the buffer tank to the process chamber when one of a signal regarding the empty level of the chemical detected by the first ultrasonic sensor and a signal regarding the overflow level of the chemical detected by the second ultrasonic sensor is provide to the controller.

In yet other embodiments, the controller keeps providing the chemical from the buffer tank to the process chamber, and simultaneously, starts supplementing the chemical from the main tank to the buffer tank when a signal regarding a supplement level of the chemical detected by the third ultrasonic sensor is provided to the controller.

In further embodiments, the controller keeps providing the chemical from the buffer tank to the process chamber, and simultaneously, suspends supplementing the chemical from the main tank to the buffer tank when a signal regarding a supplement suspension level of the chemical detected by the fourth ultrasonic sensor is provided to the controller.

In still further embodiments, the equipment further includes a vaporizer for vaporizing chemical provided from the buffer tank to provide the vaporized chemical to the process chamber.

In yet other embodiments of the present invention, chemical supplying methods for supplying chemical consumed for a semiconductor manufacturing process from a main tank to a process chamber using a semiconductor manufacturing equipment including the process chamber, the main tank, a buffer tank, and a controller, the methods include: detecting a continuous level of chemical provided to the buffer tank from the main tank, and detecting a particular level of the chemical; transmitting a signal regarding the level of the chemical to the controller; and determining whether to proceed the process and whether to supplement chemical to the buffer tank from the main tank in response to a signal regarding the level of the chemical transmitted to the controller.

In some embodiments, the determining of whether to proceed the process and whether to supplement the chemical to the buffer tank from the main tank includes: when an empty signal of the chemical is transmitted to the controller as a result of detecting a residual amount of the chemical, suspending providing chemical from the buffer tank to the process chamber; when a supplement signal of the chemical is transmitted to the controller as a result of detecting a residual amount of the chemical, keeping providing chemical from the buffer tank to the process chamber, and simultaneously, supplementing chemical from the main tank to the buffer tank; when a supplement suspension signal of the chemical is transmitted to the controller as a result of detecting a residual amount of the chemical, keeping providing chemical from the buffer tank to the process chamber, and simultaneously, suspending supplementing chemical from the main tank to the buffer tank; and when an overflow signal of the chemical is transmitted to the controller as a result of detecting a residual amount of the chemical, suspending providing chemical from the buffer tank to the process chamber.

In other embodiments, the detecting of the continuous level of chemical includes: illuminating ultrasonic waves to a liquid surface of the chemical from a bottom surface of the buffer tank and detecting the ultrasonic waves reflected by the liquid surface to detect a level of the chemical.

In still other embodiments, the detecting of the particular level of the chemical includes: when a gap extending in a direction in which a level of the chemical changes and to which the chemical flows is filled with the chemical, and an ultrasonic signal is delivered by the medium of the chemical, detecting one of an empty warning level, a supplement supply level, a supplement suspension level, and an overflow warning level of the chemical.

In even other embodiments, the detecting of the particular level of the chemical includes using a plurality of ultrasonic sensors for detecting the empty warning level, the supplement supply level, the supplement suspension level, and the overflow warning level of the chemical, respectively, wherein an ultrasonic sensor of the plurality of ultrasonic sensors that detects the empty warning level of the chemical detects absence of the chemical more sensitively than the other ultrasonic sensors, and an ultrasonic sensor of the plurality of ultrasonic sensors that detects the overflow warning level of the chemical detects presence of the chemical more sensitively than the other ultrasonic sensors.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A liquid supplying apparatus, comprising:
a tank adapted to store a liquid within an interior thereof;
an outlet in fluid communication with the interior of the tank;
a first sensor adapted to detect a surface level of the liquid within the interior of the tank;
a probe within the interior of the tank; and
a second sensor coupled to a portion of the probe, the second sensor adapted to detect the presence of liquid adjacent to the portion of the probe.

2. The apparatus of claim 1, wherein the first sensor is located on a lower portion of the tank and comprises an ultrasonic sensor adapted to transmit an ultrasonic wave into the interior of the tank and to detect a reflected ultrasonic wave transmitted from the interior of the tank.

3. The apparatus of claim 1, further comprising a separation plate spaced apart from a bottom surface of the tank, wherein the separation plate at least partially defines the interior of the tank and wherein the first sensor is located between the separation plate and the bottom surface of the tank.

4. The apparatus of claim 3, wherein an ultrasonic sensor is spaced apart from the separation plate.

5. The apparatus of claim 3, wherein a first region of the upper surface of the separation plate is recessed with respect to a second region of the upper surface of the separation plate, wherein the first region of the upper surface of the separation plate is above the first sensor and below an end portion of the outlet.

6. The apparatus of claim 5, wherein the second region of the upper surface of the separation plate is above the end portion of the outlet.

7. The apparatus of claim 1, wherein the probe is positionally fixed within the interior of the tank.

8. The apparatus of claim 1, wherein the probe and the second sensor are configured such that the liquid will not contact the second sensor when the liquid is contained within the interior of the tank.

9. The apparatus of claim 1, wherein the probe comprises a gap defined therein, the gap arranged and structured to receive a portion of the liquid within the interior of the tank, wherein the second sensor is adapted to detect the presence of liquid within the gap.

10. The apparatus of claim 9, wherein the second sensor comprises an emitter and a receiver, wherein the gap is located between the emitter and receiver, wherein the emitter is adapted to emit a signal and the receiver is adapted to detect the signal.

11. The apparatus of claim 10, wherein the outlet is adapted to change a surface level of the liquid within the interior of the tank along a direction and wherein the gap extends along the direction.

12. The apparatus of claim 11, wherein a length of the probe extends along the direction.

13. The apparatus of claim 10, wherein the gap is open to a lowermost portion of the probe.

14. The apparatus of claim 10, wherein the gap is recessed from a lateral side of the probe.

15. The apparatus of claim 10, further comprising a plurality of second sensors, wherein:
a first one of the plurality of second sensors is adapted to detect an empty alarm level of liquid within the interior of the tank;
a second one of the plurality of second sensors is adapted to detect an overflow alarm level of liquid within the interior of the tank
a third one of the plurality of second sensors is adapted to detect a supplement level of liquid within the interior of the tank; and
a fourth one of the plurality of second sensors is adapted to detect a supplement suspension level of liquid within the interior of the tank.

16. The apparatus of claim 15, further comprising a plurality of probes, wherein:
the first and second ones of the plurality of second sensors are coupled to a first one of the plurality of probes; and
the third and fourth ones of the plurality of second sensors are coupled to a second one of the plurality of probes.

17. The apparatus of claim 15, wherein each of the first to fourth ones of the plurality of second sensors is configured such that a signal detected by the receiver has a first intensity when liquid is present within the gap and a signal detected by the receiver has a second intensity less than the first intensity when liquid is absent from the gap.

18. The apparatus of claim 17, wherein the first one of the plurality of second sensors is adapted to generate a signal indicating that liquid is absent from the gap when a number of detected signals having the second intensity is less than the number of detected signals having the first intensity.

19. The apparatus of claim 17, wherein the second one of the plurality of second sensors is adapted to generate a signal indicating that liquid is present within the gap when a number of detected signals having the first intensity is less than the number of detected signals having the second intensity.

20. The apparatus of claim 1, wherein the first sensor is adapted to detect a surface level of the liquid within the interior of the tank over a range of continuous levels within the interior of the tank.

21. A chemical supplying apparatus comprising:
a tank configured to store a liquid within an interior thereof;
an inlet in fluid communication with the interior of the tank, the inlet configured to supply liquid into the interior of the tank;
an outlet in fluid communication with the interior of the tank, the outlet configured to remove liquid from the interior of the tank;
a separation plate spaced apart from a bottom surface and at least partially defining the interior of the tank, wherein the separation plate comprises a recessed portion coinciding with an axis of the outlet;
a continuous sensor located between the bottom surface of the tank and the recessed portion of the separation plate, the continuous sensor adapted to detect a surface level of liquid stored within the interior of the tank over a range of continuous levels within the interior of the tank; and
a plurality of process-control sensors located within the interior of the tank, wherein the plurality of process-control sensors are configured to detect the presence of liquid at particular levels within the interior of the tank and generate signals indicating whether the interior of the tank contains less than a first threshold amount of liquid, whether the interior of the tank contains more than a second threshold amount of liquid greater than the first threshold amount, whether a supplemental amount of liquid should be supplied to the interior of the tank and whether supplying of the supplemental amount of liquid should be suspended based upon the detected presence or absence of liquid at the particular levels.

22. The apparatus of claim 21, wherein the continuous sensor is spaced apart from the separation plate and wherein a vacant space is located between the continuous sensor and the separation plate.

23. The apparatus of claim 21, wherein the outlet is configured to change a surface level of the liquid within the interior of the tank along a direction, the apparatus further comprising a plurality of probes within the interior of the tank and extending along the direction,
wherein the plurality of process-control sensors are coupled to portions of corresponding ones of the plurality of probes and are configured to detect the presence of liquid adjacent to the portions of the probe.

24. The apparatus of claim 23, wherein the plurality of probes are positionally fixed within the interior of the tank.

25. The apparatus of claim 23, wherein the plurality of probes and the plurality of process-control sensors are configured such that the liquid will not contact the plurality of process-control sensors.

26. The apparatus of claim 23, wherein the plurality of probes comprise a plurality of gaps defined therein, the plurality of gaps structured and arranged to receive a portion of the liquid within the interior of the tank, wherein the plurality of process-control sensors are configured to detect the presence of liquid within corresponding ones of the plurality of gaps.

27. The apparatus of claim 26, wherein each of the plurality of process-control sensors comprises:
an emitter for emitting ultrasonic waves; and
a receiver for detecting the ultrasonic waves emitted by the emitter,
wherein the plurality of gaps are interposed between the emitter and receiver of corresponding ones of the plurality of process-control sensors.

28. The apparatus of claim 23, wherein:
a first one of the plurality of probes includes first and second ones of the plurality of process-control sensors,
a second one of the plurality of probes includes third and fourth ones of the plurality of process-control sensors,
the first one of the plurality of process-control sensors is configured to generate a signal indicating whether the interior of the tank contains less than the first threshold amount of liquid,
the second one of the plurality of process-control sensors is configured to generate a signal indicating whether the interior of the tank contains more than the second threshold amount of liquid,
the third one of the plurality of process-control sensors is configured to generate a signal indicating whether the supplemental amount of liquid should be supplied to the interior of the tank, and
the fourth one of the plurality of process-control sensors is configured to generate a signal indicating whether the supplying of the supplemental amount of liquid can be suspended.

29. The apparatus of claim 28, wherein the first one of the plurality of process-control sensors is configured to detect the absence of liquid more sensitively than the second one of the plurality of process-control sensors.

30. The apparatus of claim 28, wherein the second one of the plurality of process-control sensors is configured to detect the presence of liquid more sensitively than the first one of the plurality of process-control sensors.

31. The apparatus of claim 21, wherein at least one of the plurality of process-control sensors is an ultrasonic sensor.

32. A semiconductor manufacturing equipment, comprising:
a process chamber adapted to perform a semiconductor manufacturing process;
a main tank adapted to store a chemical used in the process chamber;
a buffer tank coupled between the process chamber and the main tank, wherein the main tank is adapted to supply the chemical to an interior of the buffer tank and the buffer tank is structured to store the chemical in a liquefied form, wherein the buffer tank comprises:
a continuous sensor unit adapted to monitor an amount of the chemical stored within the interior of the buffer tank and to generate a signal based upon the monitored amount of the chemical; and
a process-control sensor unit adapted to detect the presence of the chemical at particular levels within the interior of the buffer tank and to generate a signal based upon the detected presence or absence of the chemical; and
a controller coupled to the main tank, the buffer tank, and the process chamber, wherein the controller is adapted to receive the signal generated by the process-control sensor unit, is adapted to control the semiconductor manufacturing process of the process chamber and is further adapted to control the main tank to supply the chemical to the interior of the buffer tank.

33. The equipment of claim 32, wherein the continuous sensor unit is located on a lower portion of the buffer tank and comprises an ultrasonic sensor adapted to transmit an ultrasonic wave to a surface of the chemical within the interior of the buffer tank and to detect a reflected ultrasonic wave transmitted from the interior of the buffer tank.

34. The equipment of claim 32, further comprising a display unit adapted to receive the signal generated by the continuous sensor unit and to display the monitored amount of the chemical stored within the interior of the buffer tank.

35. The equipment of claim 32, wherein the process-control sensor unit comprises:
at least one probe within the interior of the tank and extending along a direction in which a level of the chemical changes during the semiconductor manufacturing process; and
a plurality of process-control sensors arranged at portions of the at least one probe along the extended direction of the probe, wherein the plurality of process-control sensors are adapted to detect the presence of the chemical adjacent to the portions of the at least one probe.

36. The equipment of claim 35, wherein the at least one probe comprises a plurality of gaps arranged and structured to receive the chemical and the plurality of process-control sensors are adapted to detect the presence of the chemical within corresponding ones of the plurality of gaps.

37. The equipment of claim 35, wherein:
a first one of the plurality of process-control sensors is arranged at a lowermost position of the at least one probe and is adapted to detect an empty alarm level of the chemical within the interior of the buffer tank;
a second one of the plurality of process-control sensors is arranged at an uppermost position of the at least one probe and is adapted to detect an overflow alarm level of the chemical within the interior of the buffer tank;
a third one of the plurality of process-control sensors is arranged at a position of the at least one probe that is elevationally between the first and second ones of the plurality of process-control sensors, wherein the third one of the plurality of process-control sensors is adapted to detect a supplement level of the chemical within the interior of the buffer tank; and
a fourth one of the plurality of process-control sensors is arranged at a position of the at least one probe that is elevationally between the second and third ones of the plurality of process-control sensors, wherein the fourth one of the plurality of process-control sensors is adapted to detect an supplement suspension level of the chemical within the interior of the buffer tank.

38. The equipment of claim 37, wherein:
the first one of the plurality of process-control sensors is further adapted to generate an empty alarm signal corresponding to the detected empty alarm level of the chemical within the interior of the buffer tank;
the second one of the plurality of process-control sensors is further adapted to generate an overflow alarm signal corresponding to the detected overflow alarm level of the chemical within the interior of the buffer tank; and
the controller is further adapted to receive the empty alarm signal and overflow alarm signal and to prevent the chemical from being provided from the buffer tank to the process chamber when at least one of the empty alarm signal and the overflow alarm signal is received.

39. The equipment of claim 37, wherein:
the third one of the plurality of process-control sensors is further adapted to generate a supplement supply signal corresponding to the detected supplement level of the chemical within the interior of the buffer tank; and
the controller is further adapted to receive the supplement supply signal, to permit the chemical to be provided from the buffer tank to the process chamber and to permit the chemical to be supplied to the interior of the buffer tank from the main tank when the supplement supply signal is received.

40. The equipment of claim 39, wherein the controller is further adapted to permit the chemical to be provided from the buffer tank to the process chamber while permitting the chemical to be supplied to the interior of the buffer tank from the main tank.

41. The equipment of claim 37, wherein:
the fourth one of the plurality of process-control sensors is further adapted to generate a supplement supply suspension signal corresponding to the detected supplement suspension level of the chemical within the interior of the buffer tank; and
the controller is further adapted to receive the supplement supply suspension signal, to permit the chemical to be provided from the buffer tank to the process chamber and to prevent the chemical from being supplied to the interior of the buffer tank from the main tank when the supplement supply suspension signal is received.

42. The equipment of claim 41, wherein the controller is further adapted to permit the chemical to be provided from the buffer tank to the process chamber while preventing the chemical from being supplied to the interior of the buffer tank from the main tank.

43. The equipment of claim 32, further comprising a vaporizer coupled between the buffer tank and the process chamber, the vaporizer adapted to vaporize the chemical provided from the buffer tank and provide the vaporized chemical to the process chamber.

44. A method of manufacturing a semiconductor device, the method comprising:
detecting the presence of a chemical contained within an interior of a first tank at particular levels within the interior of the first tank, wherein the first tank is coupled to a process chamber that is configured to perform a semiconductor manufacturing process using the chemical;
generating a signal based on the detecting; and
determining whether to permit the semiconductor manufacturing process to be performed and whether to permit a supplemental amount of the chemical to be supplied from a second tank to the first tank based upon the generated signal.

45. The method of claim 44, wherein determining whether to permit the semiconductor manufacturing process to be performed and whether to permit the supplemental amount of the chemical to be supplied comprises:
preventing the chemical from being transferred outside the interior of the first tank when the generated signal is an empty alarm signal indicating that the first tank contains less than a first threshold amount of the chemical;
permitting the chemical to be transferred from the first tank to the process chamber and permitting the supplemental amount of the chemical to be supplied from the second tank to the first tank when the generated signal is a supplement supply signal indicating that a supplemental amount of the chemical should be supplied to the first tank;
permitting the chemical to be transferred from the first tank to the process chamber and preventing a supplemental amount of the chemical from being supplied from the second tank to the first tank when the generated signal is a supplement supply suspension signal indicating that a supplemental amount of the chemical should not be supplied to the first tank; and
preventing the chemical from being transferred outside the interior of the first tank when the generated signal is an overflow alarm signal indicating that the first tank contains more than a second threshold amount of the chemical greater than the first threshold amount.

46. The method of claim 44, further comprising monitoring a level of the chemical contained within the interior of a first tank over a range of continuous levels within the interior of the first tank.

47. The method of claim 46, wherein monitoring the level of the chemical comprises transmitting ultrasonic waves through the chemical in the interior of the first tank and detecting reflected ultrasonic waves transmitted through the chemical.

48. The method of claim 44, wherein the particular levels comprise an empty alarm level of the chemical within the interior of the first tank, a supplement supply level of the chemical within the interior of the first tank, a supplement suspension level of the chemical within the interior of the first tank, and an overflow alarm level of the chemical within the interior of the first tank.

49. The method of claim 48, wherein the detecting the presence of the chemical comprises arranging a plurality of process-control sensors at a corresponding plurality of levels within the interior of the first tank, wherein the plurality of levels include the empty alarm level, the supplement supply level, the supplement suspension level, and the overflow alarm level.

50. The method of claim 48, wherein
one of the plurality of process-control sensors arranged at the empty alarm level of the interior of the first tank is configured to detect the absence of the chemical more sensitively than the others of the plurality of process-control sensors, and
one of the plurality of process-control sensors arranged at the overflow alarm level of the interior of the first tank is configured to detect the presence of the chemical more sensitively than the others of the plurality of process-control sensors.

51. The method of claim 48, wherein at least one of the process-control sensors is an ultrasonic sensor.
